(19) United States
(12) Patent Application Publication
(10) Pub. No.: US 2025/0321142 A1
(43) Pub. Date: Oct. 16, 2025

(54) DEVICE AND METHOD OF ESTIMATING JUNCTION TEMPERATURE OF POWER MODULE WHEN DRIVING MOTOR AT LOW SPEED

(71) Applicants: Hyundai Motor Company, Seoul (KR); Kia Corporation, Seoul (KR)

(72) Inventors: Yeong Ju KOH, Suncheon-Si (KR); Je Hwan LEE, Seongnam-Si (KR); Myung Ho KIM, Incheon (KR); Young Su KO, Hwaseong-Si (KR); Kang Ho JEONG, Hwaseong-Si (KR); Young Seul LIM, Seoul (KR)

(73) Assignees: Hyundai Motor Company, Seoul (KR); Kia Corporation, Seoul (KR)

(21) Appl. No.: 18/945,269

(22) Filed: Nov. 12, 2024

(30) Foreign Application Priority Data
Apr. 15, 2024 (KR) 10-2024-0050307

(51) Int. Cl. G01K 7/01

(52) U.S. Cl. CPC G01K 7/01; G01K 2217/00

(57) ABSTRACT

A device for estimating a junction temperature of a power module at time of low-speed driving of a motor includes one or more processors, and a storage medium operatively connected to the one or more processors and storing computer-readable instructions. When computer-readable instructions are executed by one or more processors, one or more processors are configured to determine a ripple of a maximum conduction loss due to conduction of power module at time of low-speed driving of motor, estimate a temperature ripple of power module from ripple of maximum conduction loss, and estimate junction temperature of power module by adding a junction temperature change of power module at time of high-speed driving of motor and a temperature of a coolant for cooling power module to temperature ripple. Temperature ripple of power module is estimated using a thermal model.

### CROSS-REFERENCE TO RELATED APPLICATION(S)

The present application claims priority to Korean Patent Application No. 10-2024-0050307 filed on Apr. 15, 2024, the entire contents of which is incorporated herein for all purposes by this reference.

### BACKGROUND OF THE PRESENT DISCLOSURE

### Field of the Present Disclosure

The present disclosure relates to a device and method of estimating a junction temperature of a power module when a motor is driven at low speed.

### Description of Related Art

Inverters receive direct current power from batteries and supply three-phase alternating current power to motors. At the instant time, a power module inside the inverter switches at a high frequency. Due to the resulting switching loss and conduction loss (hereinafter referred to as ‘power loss’), the power module generates heat at a high temperature. If heat is generated at a temperature higher than a rated temperature of the device, it may lead directly to loss of the power module, and thus, managing the temperature of the power module in real time may be important in the development of an inverter.

The temperature of the power module generates ripples when the motor is driven at low speeds, and when driven at high speeds, the size of ripples decreases and converges to a specific value. Temperature ripple occurring when the motor is driven at low speed causes overtemperature in the power module. At the instant time, if derating is not performed, excessive stress may be applied to the device, and thus, accurately estimating the temperature of a power module may be required for derating during low-speed operation of the motor.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing an apparatus and method of estimating a junction temperature of a power module when a motor is driven at low speed, in which the junction temperature of the power module while driving of the motor at low speed may be accurately estimated.

According to an aspect of the present disclosure, a device for estimating a junction temperature of a power module at the time of low-speed driving of a motor includes one or more processors; and a storage medium operatively connected to the one or more processors and storing computer-readable instructions. By executing the computer-readable instructions, the one or more processors are configured to; determine a ripple of a maximum conduction loss due to conduction of the power module at the time of the low-speed driving of the motor, estimate a temperature ripple of the power module from the ripple of the maximum conduction loss, and estimate the junction temperature of the power module by adding an amount of change in the junction temperature of the power module at the time of high-speed driving of the motor and a temperature of a coolant for cooling the power module to the temperature ripple. The temperature ripple of the power module is estimated using a thermal model.

The high-speed driving may be a driving condition of the motor in which an average conduction loss of the power module is constant over time and a ripple of conduction loss is within an error range, and the low-speed driving may be a driving condition of the motor in which the average conduction loss of the power module varies over time and the ripple of the conduction loss is outside of the error range.

The thermal model may be a model for estimating the temperature ripple of the power module from conduction loss due to conduction of the power module.

The one or more processors may be configured for estimating the temperature ripple of the power module by multiplying the ripple of the maximum conduction loss by a gain of the thermal model.

The thermal model may be an RC filter in which a resistor and a capacitor are connected in parallel, and may be a model in which the RC filter is provided as at least two RC filters connected in series.

The amount of change in the junction temperature of the power module at the time of the high-speed driving of the motor may be a value obtained by multiplying power loss during the high-speed driving of the motor by thermal resistance, the power loss including conduction loss and switching loss of the power module.

The ripple (RMCL) of the maximum conduction loss may be obtained according to equation:

$$R M C L = \frac{{I}_{max} ( {I}_{max} \times R + {V}_{c e o} )}{2} \times \frac{1}{2} \times ( 1 + MI ) ,$$

where Iₘₐₓ is a maximum value of a three-phase current, R is turn-on resistance of the power module, V_{ceo} is a maximum voltage of the power module, and MI is a modulation index.

The maximum value of the three-phase current may be obtained based on a d-axis current and a q-axis current through dq conversion of the three-phase current.

The maximum value of the three-phase current may be obtained according to equation:

$${I}_{} = \sqrt{{I}_{d}^{2} + {I}_{q}^{2}} / \sqrt{2}$$

where Iₘₐₓ is the maximum value of the three-phase current, I_{d} is the d-axis current, and I_{q} is the q-axis current.

According to an aspect of the present disclosure, a method of estimating a junction temperature of a power module at the time of low-speed driving of a motor includes determining a ripple of a maximum conduction loss due to conduction of the power module at the time of the low-speed driving of the motor; estimating a temperature ripple of the power module from the ripple of the maximum conduction loss; and estimating the junction temperature of the power module by adding an amount of change in the junction temperature of the power module at the time of high-speed driving of the motor and a temperature of a coolant for cooling the power module to the temperature ripple. In the estimating of the temperature ripple of the power module, the temperature ripple of the power module is estimated using a thermal model.

The high-speed driving may be a driving condition of the motor in which an average conduction loss of the power module is constant over time and a ripple of conduction loss is within an error range, and the low-speed driving may be a driving condition of the motor in which the average conduction loss of the power module varies over time and the ripple of the conduction loss is outside of the error range.

The thermal model may be a model for estimating the temperature ripple of the power module from conduction loss due to conduction of the power module.

The estimating of the temperature ripple of the power module may include estimating the temperature ripple of the power module by multiplying the ripple of the maximum conduction loss by a gain of the thermal model.

The thermal model may be an RC filter in which a resistor and a capacitor are connected in parallel, and may be a model in which the RC filter is provided as at least two RC filters connected in series.

The amount of change in the junction temperature of the power module at the time of the high-speed driving of the motor may be a value obtained by multiplying power loss during the high-speed driving of the motor by thermal resistance, the power loss including conduction loss and switching loss of the power module.

The ripple (RMCL) of the maximum conduction loss may be obtained according to equation:

$$RMCL = \frac{{I}_{} ( {I}_{max} \times R + {V}_{ceo} )}{2} \times \frac{1}{2} \times ( 1 + MI ) ,$$

where Iₘₐₓ is a maximum value of a three-phase current, R is turn-on resistance of the power module, V_{ceo} is a maximum voltage of the power module, and MI is a modulation index.

The maximum value of the three-phase current may be obtained based on a d-axis current and a q-axis current through dq conversion of the three-phase current.

The maximum value of the three-phase current may be obtained according to equation:

$$RMCL = \frac{{I}_{} ( {I}_{max} \times R + {V}_{ceo} )}{2} \times \frac{1}{2} \times ( 1 + MI ) ,$$

where Iₘₐₓ is the maximum value of the three-phase current, I_{d} is the d-axis current, and I_{q} is the q-axis current.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF DRAWINGS

FIG. 1 is a diagram illustrating the configuration of an inverter to which a device for estimating a junction temperature of a power module is applied when a motor is driven at low speed according to an exemplary embodiment of the present disclosure.

FIG. 2 is a diagram illustrating the configuration of a device for estimating a junction temperature of a power module when a motor is driven at low speed according to an exemplary embodiment of the present disclosure.

FIG. 3 is a diagram illustrating a thermal model according to an exemplary embodiment of the present disclosure.

FIG. 4 is a diagram illustrating simulation results according to an exemplary embodiment of the present disclosure.

FIG. 5A is a diagram illustrating a phase current and a junction temperature of a power module before application of the present disclosure in a low-speed driving region of a motor.

FIG. 5B is a diagram illustrating a phase current and a junction temperature of a power module after application of the present disclosure in a low-speed driving region of a motor.

FIG. 6 is a flowchart illustrating a method of estimating a junction temperature of a power module when a motor is driven at low speed according to an exemplary embodiment of the present disclosure.

FIG. 7 is a block diagram of a computing device which may fully or partially implement a device for estimating a junction temperature of a power module when a motor is driven at low speed according to an exemplary embodiment of the present disclosure.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, specific embodiments will be described with reference to the drawings. The detailed description below is provided to provide a comprehensive understanding of the methods, devices and/or systems described herein. However, this is only an example and the present disclosure is not limited thereto.

In describing the embodiments, if it is determined that the detailed description of the known technology related to the present disclosure may unnecessarily obscure the subject matter of the present disclosure, the detailed description will be omitted. Furthermore, terms to be described later are terms defined based on functions in an exemplary embodiment of the present disclosure, which may vary according to the intention or custom of a user or operator. Therefore, the definition should be made based on the contents throughout the present specification. Terminology used in the detailed description is only for describing the exemplary embodiments and should not be taken as limiting. Unless expressly used otherwise, singular forms of expression include plural forms. In the present description, expressions such as “including” and “comprising” are intended to indicate any characteristic, number, step, operation, elements, portion or combination thereof, and it should not be construed as excluding the existence or possibility of one or more other characteristics, numbers, steps, operations, elements, portions or combinations thereof other than those described.

In an exemplary embodiment of the present disclosure, high-speed driving may refer to driving conditions of the motor when the average conduction loss of the power module 1 is constant over time and the ripple of the conduction loss is within an error range.

Furthermore, in an exemplary embodiment of the present disclosure, low-speed driving may refer to driving conditions of the motor when the average conduction loss of the power module 1 varies over time and the ripple of the conduction loss is outside of the error range.

The rotation speed of the motor when driven at high speed or low speed includes a value which may vary depending on the rating of the motor, and is not limited to a specific value in an exemplary embodiment of the present disclosure.

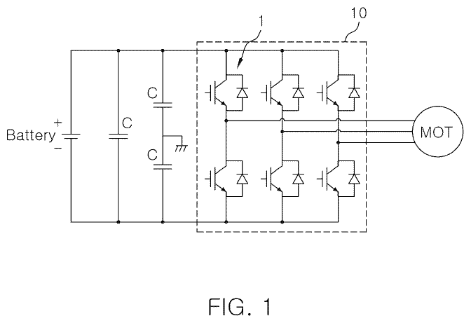

FIG. 1 is a diagram illustrating the configuration of an inverter to which a device for estimating a junction temperature of a power module is applied when a motor is driven at low speed according to an exemplary embodiment of the present disclosure.

As illustrated in FIG. 1, an inverter 10 may be a module for driving a motor MOT by converting the direct current (DC) component stored in the capacitor C, which smoothes and stores the power of the battery, into alternating current (AC) component, and may include a plurality of power modules 1. The power module 1 includes an Insulated Gate Bipolar mode Transistor (IGBT) and a diode, and the present power module 1 may be attached to a heat sink through which coolant flows to prevent overheating.

Meanwhile, as the power module 1 repeatedly turns on or off, power loss may occur. Power loss includes conduction loss due to conduction of the power module 1 and switching loss due to switching, and may be expressed in units of watts (W). Each loss may be calculated using a preset conduction loss equation and a switching loss equation.

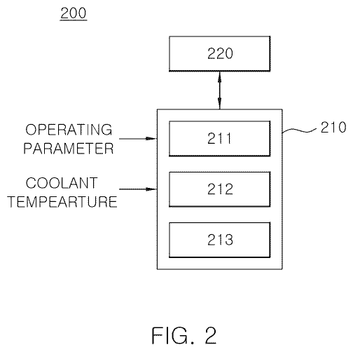

These conduction loss calculation formulas and switching loss calculation formulas may be stored in advance in a memory 220 (illustrated in FIG. 2), which will be described later. The calculation formula for determining the power loss of the power module 1 may be set in advance by considering various parameters depending on the characteristics of the inverter to which the type of the power module 1 (IGBT, diode, or the like) is applied, and may be determined in various manners depending on the company that manufactures the power module 1 or the company that manufactures products such as vehicles by applying the power module 1. In the instant case, the voltage and current provided to the power module 1, the switching frequency of the power module 1, and the like may be considered as parameters mainly used to determine conduction loss or switching loss.

On the other hand, if the junction temperature of the power module 1 increases due to power loss, excessive stress may be applied to the power module 1. When the junction temperature of the power module 1 becomes too high, derating or temporary stopping is performed to forcibly reduce the performance of the power module 1.

FIG. 2 is a diagram illustrating the configuration of a device for estimating a junction temperature of a power module when a motor is driven at low speed according to an exemplary embodiment of the present disclosure.

As illustrated in FIG. 2, a device 200 for estimating a junction temperature of a power module when the motor is driven at low speed includes a control module 210 and a memory 220, and the control module 210 may include a first module 211, a second control module, and a third module 213.

When the above-described motor is driven at low speed, the device 200 for estimating a junction temperature of a power module may include a processor (for example, a computer, a microprocessor, a CPU, an ASIC, a logic circuit, or the like) and a memory storing software instructions providing various functions when executed by the processor. In the instant case, the processor and the memory may be implemented as separate semiconductor circuits. Alternatively, the processor and the memory may be implemented as a single integrated semiconductor circuit. The processor may be one or more processors.

The control module 210 may estimate the junction temperature of the power module when the motor is driven at low speed based on the operating parameters and coolant temperature. In the instant case, the operating parameters may include various parameters for estimating a junction temperature of the power module, such as voltage, current, and switching frequency.

In detail, the first module 211 may be configured to determine the ripple of the maximum conduction loss due to conduction of the power module 1 when the motor MOT is driven at low speed according to Equation 1 below.

$$RMCL = \frac{{I}_{} ( {I}_{max} \times R + {V}_{ceo} )}{2} \times \frac{1}{2} \times ( 1 + MI ) \qquad [ Equation 1 ]$$

In the instant case, RMCL refers to the ripple of the maximum conduction loss, Iₘₐₓ refers to a maximum value of a three-phase current, R refers to the turn-on resistance of the power module, V_{ceo} refers to the maximum voltage of the power module, and MI (Modulation Index) refers to the modulation index.

The maximum value Iₘₐₓ of the above-mentioned three-phase current may be obtained according to Equation 2 below based on the d-axis current and q-axis current through dq conversion of the three-phase current.

$${I}_{} = \sqrt{{I}_{d}^{2} + {I}_{q}^{2}} / \sqrt{2} \qquad [ Equation 2 ]$$

In the instant case, Iₘₐₓ is the maximum value of the three-phase current, I_{d} may be the d-axis current, and I_{q} may be the q-axis current.

Meanwhile, the second module 212 may estimate the temperature ripple RT of the power module 1 from the ripple of the maximum conduction loss (RMCL).

In detail, the second module 212 may estimate the temperature ripple of the power module using a thermal model, and for example, the temperature ripple RT of the power module 1 may be estimated by multiplying the ripple of the maximum conduction loss (RMCL) by a gain G of the thermal model according to Equation 3 below.

$$RT = RMCL \times G \qquad [ Equation 3 ]$$

In the instant case, RT may be the temperature ripple of the power module, RMCL may be the ripple of the maximum conduction loss, and G may be the gain of the thermal model.

The above-mentioned thermal model is a model for estimating the temperature ripple of the power module 1 from the conduction loss caused by the conduction of the power module 1.

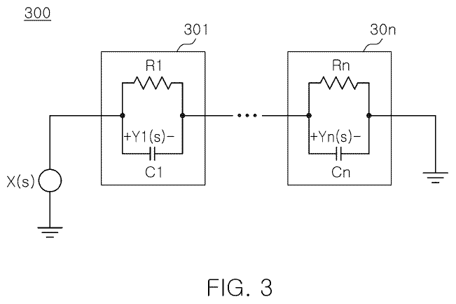

FIG. 3 is a diagram illustrating a thermal model according to an exemplary embodiment of the present disclosure.

As illustrated in FIG. 3, a thermal model 300 may be an RC filter in which a resistor R and a capacitor C are connected in parallel, and a plurality of RC filters (301 to 30n, where n is a natural number) may be connected in series.

According to the present thermal model, the thermal model may be represented by a transfer function in which the input X(s) is the conduction loss and the output Y1(s), . . . , Yn(s) is the temperature ripple, which is illustratively shown in Equation 4 below. The present transfer function may be a gain of the thermal model.

$$G = \frac{{R}_{1}}{\sqrt{( 1 + {R}_{1}^{2} \times {w}^{2} \times {C}_{1}^{2} )}} + … + \frac{{R}_{n}}{\sqrt{( 1 + {R}_{n}^{2} \times {w}^{2} \times {C}_{n}^{2} )}} \qquad [ Equation 4 ]$$

In the third module 213, according to Equation 5 below, by adding the junction temperature change amount T1 of the power module 1 when the motor MOT is driven at high speed and the temperature T2 of the coolant for cooling the power module 1 to the temperature ripple RT, the junction temperature TJ of the power module 1 when the motor MOT is driven at low speed may be estimated. In the instant case, the temperature of the coolant may be replaced by the temperature of the heat sink.

$$TJ = RT + T 1 + T 2 \qquad [ Equation 5 ]$$

In the instant case, RT may be the temperature ripple, T1 may be the amount of change in junction temperature of the power module when the motor MOT is driven at high speed, and T2 may be the temperature of the coolant for cooling the power module 1.

For example, the junction temperature TJ of the power module 1 when the motor MOT is driven at low speed may be a value obtained by adding the temperature ripple RT of the power module 1 when the motor MOT is driven at low speed, to the junction temperature TJ (for example, T1+T2) of the power module 1 when the motor MOT is driven at high speed.

The junction temperature change amount T1 of the power module 1 when the above-mentioned motor MOT is driven at high speed may be obtained by multiplying the power loss when the motor MOT is driven at high speed by the thermal resistance, and the power loss may include conduction loss and switching loss of the power module.

In the instant case, thermal resistance may be represented as the value of temperature change amount (ΔT) divided by power loss. For example, when the thermal resistance is 0.2 [° C./W] and the power loss is 200 [W], the temperature change amount (ΔT) may be 0.2 [° C./W]×200 [W]=40 [C].

This thermal resistance may be obtained experimentally in advance through a driving test with an object (for example, a motor) supplied with power by the power module 1, and the thermal resistance previously derived by the present experimental method may be stored in the memory 220.

The method of determining thermal resistance in advance is briefly described as follows. The power module 1 may be driven by determining in advance the parameters of the power module (for example, input voltage, input current, and switching frequency of the power module) for obtaining the power loss of the power module 1, and the temperature of the power module 1 may be obtained by a temperature sensor (for example, a thermal imaging camera or the like), determining thermal resistance by checking the change trend of the obtained temperature.

For example, when power loss occurs in the power module 1, the temperature of the power module 1 rises with the characteristics of thermal resistance and reaches a saturation state. At the instant time, the temperature change value (for example, the final temperature in the saturated state and the starting temperature before applying the current) may be easily confirmed using a thermal imaging camera or the like by applying experimental methods thereto.

Therefore, thermal resistance may be calculated through the amount of temperature change of the power module obtained by a thermal imaging camera and the power loss obtained through the input parameters (current, voltage, switching frequency) of the power module during the experiment. For example, in experiments, thermal resistance may be determined by dividing the temperature change amount by the power loss.

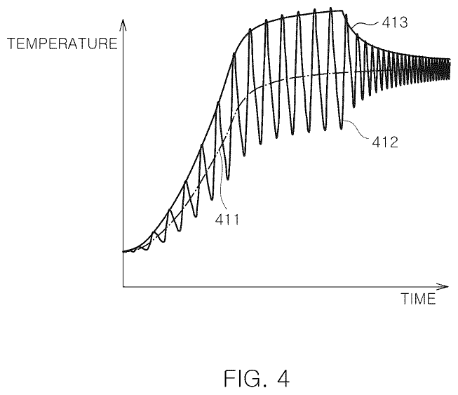

FIG. 4 is a diagram illustrating simulation results according to an exemplary embodiment of the present disclosure. Reference numeral 411 denotes the junction temperature of the power module during high-speed driving obtained through simulation, reference numeral 412 denotes temperature ripple during low-speed driving obtained through simulation, and reference numeral 413 indicates the maximum value of temperature ripple during low-speed driving obtained through simulation.

As illustrated in FIG. 4, it may be seen that when the motor MOT is driven at low speed, the junction temperature of the power module during high-speed driving of the motor MOT becomes a DC component, and the temperature ripple during low-speed driving of the motor MOT becomes a DC component.

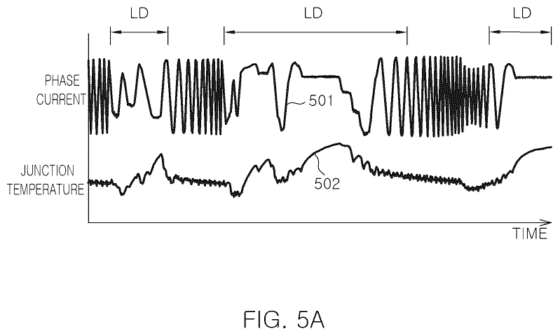

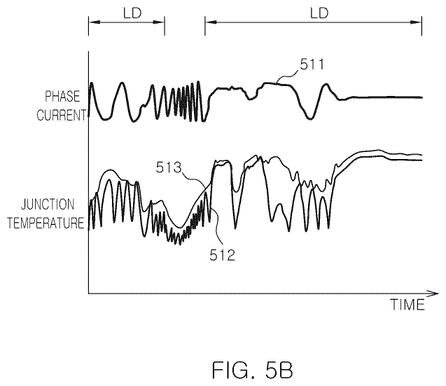

Meanwhile, FIG. 5A is a diagram illustrating the phase current and junction temperature of the power module before application of the present disclosure in the low-speed driving region of the motor. Reference numeral 501 refers to the phase current, and reference numeral 502 refers to the actual junction temperature of the power module 1 in the low speed region LD.

In FIG. 5A, the low-speed driving region LD refers to an area in which the motor MOT is driven at low speed, and the temperature ripple of the actual junction temperature 502 of the power module 1 is greater than the temperature ripple in other areas (for example, high-speed driving region), but it is not possible to accurately estimate in the related art.

On the other hand, FIG. 5B is a diagram illustrating the phase current and junction temperature of the power module after application of the present disclosure in the low-speed driving region of the motor. Reference numeral 511 refers to the phase current, reference numeral 512 refers to the actual junction temperature of the power module 1 in the low-speed region LD, and reference numeral 513 refers to the estimated junction temperature of the power module 1 in the low-speed region LD.

As illustrated in FIG. 5B, in various exemplary embodiments of the present disclosure, it may be seen that the junction temperature 513 of the power module 1 estimated in the low-speed region LD well estimates a maximum value of the temperature ripple of the actual junction temperature 512 of the power module 1 in the low-speed region LD.

Meanwhile, in the memory 220, various data including operating parameters, thermal models, the above-mentioned mathematical equations, and the like may be stored in advance, and programs for implementing various operations of the above-described control module 210 may be stored.

As described above, according to an exemplary embodiment of the present disclosure, the temperature ripple of the power module is estimated from the ripple of the maximum conduction loss due to conduction of the power module when the motor is driven at low speed, and by adding the junction temperature change amount of the power module when the motor is driven at high speed and the temperature of the coolant for cooling the power module to the estimated temperature ripple to estimate the junction temperature of the power module, the junction temperature of the power module may be accurately estimated when the motor is driven at low speed.

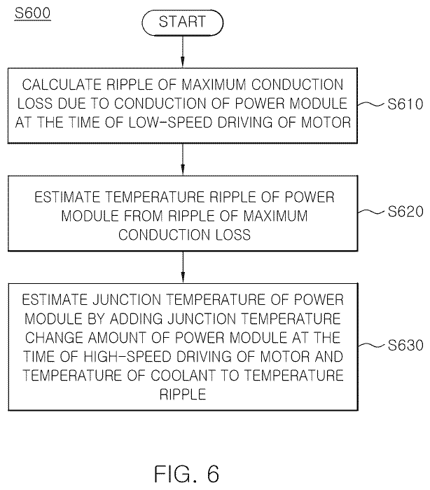

Meanwhile, FIG. 6 is a flowchart illustrating a method of estimating a junction temperature of a power module when driving a motor at low speed according to an exemplary embodiment of the present disclosure.

Hereinafter, a method of estimating a junction temperature of a power module when driving a motor at low speed according to an exemplary embodiment will be described with reference to FIGS. 1 to 6. However, for simplification of the present disclosure, descriptions overlapping with FIG. 1, FIG. 2, FIG. 3, FIG. 4, and FIG. 5 are omitted.

Referring to FIGS. 1 to 6, a method (S600) of estimating a junction temperature of a power module when driving a motor at low speed according to various exemplary embodiments of the present disclosure may be started by calculating the ripple of the maximum conduction loss due to conduction of the power module 1 when the motor is driven at low speed (S610). As described above, the ripple of the maximum conduction loss may be calculated through Equations 1 and 2 described above.

Furthermore, as described above, low-speed driving refers to the driving conditions of the motor when the average conduction loss of the power module 1 varies over time and the ripple of the conduction loss is outside of the error range.

Thereafter, the device 200 for estimating a junction temperature of a power module may estimate the temperature ripple RT of the power module 1 from the ripple of the maximum conduction loss (RMCL) (S620).

In detail, the device 200 for estimating a junction temperature of a power module may estimate the temperature ripple of the power module 1 when the motor MOT is driven at low speed, using a thermal model. For example, as described above, the temperature ripple RT of the power module 1 when the motor MOT is driven at low speed may be estimated by multiplying the ripple of the maximum conduction loss (RMCL) by the gain G of the thermal model according to Equation 3 above.

Furthermore, the above-described thermal model is a model for estimating the temperature ripple of the power module 1 from the conduction loss due to conduction of the power module 1, and as described above, is an RC filter in which a resistor and a capacitor are connected in parallel and may be a model in which at least two RC filters are connected in series.

Lastly, the device 200 for estimating a junction temperature of a power module may estimate the junction temperature TJ of the power module 1 when the motor MOT is driven at low speed, by adding the junction temperature change amount T1 of the power module 1 when the motor MOT is driven at high speed and the temperature T2 of the coolant for cooling the power module 1, to the temperature ripple RT (S630).

As described above, high-speed driving may refer to the driving conditions of the motor when the average conduction loss of the power module 1 is constant over time and the ripple of the conduction loss is within the error range.

Furthermore, as described above, Equation 5 may be used to estimate the junction temperature TJ of the power module 1 when the motor MOT is driven at low speed.

Furthermore, the junction temperature change amount T1 of the power module 1 when the motor MOT is driven at high speed may be obtained by multiplying the power loss when the motor MOT is driven at high speed by the thermal resistance, and as described above, power loss may include conduction loss and switching loss of the power module.

As described above, according to an exemplary embodiment of the present disclosure, the temperature ripple of the power module may be estimated from the ripple of the maximum conduction loss due to conduction of the power module when the motor is driven at low speed, and the junction temperature of the power module may be estimated by adding the junction temperature change amount of the power module when the motor is driven at high speed and the temperature of the coolant for cooling the power module to the estimated temperature ripple, accurately estimating the junction temperature of the power module when the motor is driven at low speed.

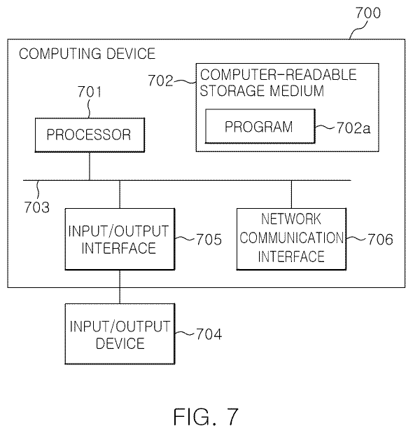

On the other hand, FIG. 7 is a block diagram of a computing device 700 which may fully or partially implement the device 200 for estimating a junction temperature of a power module when a motor is driven at low speed according to an exemplary embodiment of the present disclosure.

As illustrated in FIG. 7, the computing device 700 includes at least one processor 701, a computer-readable storage medium 702, and a communication bus 703.

The processor 701 may enable the computing device 700 to operate according to the example embodiments mentioned above. For example, the processor 701 may execute one or more programs stored in the computer-readable storage medium 702. The one or more programs may include one or more computer-executable instructions, and the computer-executable instructions, when executed by the processor 701, may be configured to cause the computing device 700 to perform operations according to example embodiments.

The computer-readable storage medium 702 is configured to store computer-executable instructions or program code, program data, and/or other suitable forms of information. A program 702a stored in the computer-readable storage medium 702 includes a set of instructions executable by the processor 701. In an exemplary embodiment of the present disclosure, the computer-readable storage medium 702 may be a memory (a volatile memory, such as a random access memory, a non-volatile memory, or an appropriate combination thereof), one or more magnetic disk storage devices, optical disk storage devices, flash memory devices, other forms of storage media which may be accessed by the computing device 700 and store required information, or a suitable combination thereof.

The communication bus 703 interconnects various other components of the computing device 700, including the processor 701 and the computer-readable storage medium 702.

The computing device 700 may also include one or more network communication interfaces 706 and one or more input/output interfaces 705 providing an interface for one or more input/output devices 704. The input/output interface 705 and the network communication interface 706 are connected to the communication bus 703. The network may be any one of cellular networks, such as Global System for Mobile Communications (GSM), Enhanced Data Rates for GSM Evolution (EDGE), General Packet Radio Service (GPRS), Code Division Multiple Access (CDMA), Time Division-CDMA (TD-CDMA), a Universal Mobile Telecommunications System (UMTS), Long Term Evolution (LTE), or other cellular networks.

The input/output device 704 may be connected to other components of the computing device 700 through the input/output interface 705. As an exemplary embodiment of the present disclosure, the input/output device 704 may include input devices such as pointing devices (such as a mouse, a trackpad or the like), keyboards, touch input devices (such as a touchpad, a touch screen, or the like), voice or audio input devices, various types of sensor devices and/or imaging devices, and/or output devices such as display devices, printers, speakers, and/or network cards. The illustrative input/output device 704 may be included within the computing device 700, as a component forming the computing device 700, or may be connected to the computing device 700, as a separate device distinct from the computing device 700.

On the other hand, various exemplary embodiments of the present disclosure may include a program for performing the methods described in the present specification on a computer, and a computer-readable recording medium containing the program. The computer-readable recording medium may include program instructions, local data files, local data structures, and the like, singly or in combination. The medium may be those specifically designed and constructed for the present disclosure, or may be those commonly available in the computer software field. Examples of the computer-readable recording medium include magnetic media such as hard disks, floppy disks and magnetic tapes, optical recording media such as CD-ROM and DVD, and a hardware device specially configured to store and execute program instructions, such as ROM, RAM, flash memory, and the like. Examples of the programs may include not only machine language code such as that produced by a compiler, but also high-level language code which may be executed by a computer using an interpreter or the like.

As set forth above, according to an exemplary embodiment of the present disclosure, a temperature ripple of a power module may be estimated from the ripple of a maximum conduction loss due to conduction of the power module when the motor is driven at low speed, and a junction temperature change amount of the power module when the motor is driven at high speed and a temperature of coolant for cooling the power module may be added to the estimated temperature ripple to estimate the junction temperature of the power module, accurately estimating the junction temperature of the power module when the motor is driven at low speed.

In various exemplary embodiments of the present disclosure, the scope of the present disclosure includes software or machine-executable commands (e.g., an operating system, an application, firmware, a program, etc.) for enabling operations according to the methods of various embodiments to be executed on an apparatus or a computer, a non-transitory computer-readable medium including such software or commands stored thereon and executable on the apparatus or the computer.

In various exemplary embodiments of the present disclosure, the control device may be implemented in a form of hardware or software, or may be implemented in a combination of hardware and software.

Software implementations may include software components (or elements), object-oriented software components, class components, task components, processes, functions, attributes, procedures, subroutines, program code segments, drivers, firmware, microcode, data, database, data structures, tables, arrays, and variables. The software, data, and the like may be stored in memory and executed by a processor. The memory or processor may employ a variety of means well known to a person including ordinary knowledge in the art.

Furthermore, the terms such as “unit”, “module”, etc. included in the specification mean units for processing at least one function or operation, which may be implemented by hardware, software, or a combination thereof.

In the flowchart described with reference to the drawings, the flowchart may be performed by the controller or the processor. The order of operations in the flowchart may be changed, multiple operations may be merged, or any operation may be divided, and a specific operation may not be performed. Furthermore, the operations in the flowchart may be performed sequentially, but not necessarily performed sequentially. For example, the order of the operations may be changed, and at least two operations may be performed in parallel.

Hereinafter, the fact that pieces of hardware are coupled operatively may include the fact that a direct and/or indirect connection between the pieces of hardware is established by wired and/or wirelessly.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the present specification, unless stated otherwise, a singular expression includes a plural expression unless the context clearly indicates otherwise.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. An apparatus for estimating a junction temperature of a power module at a time of low-speed driving of a motor, the apparatus comprising:
one or more processors; and
a storage medium operatively connected to the one or more processors and storing computer-readable instructions,
wherein by executing the computer-readable instructions, the one or more processors are configured to:
determine a ripple of a maximum conduction loss due to conduction of the power module at the time of the low-speed driving of the motor,
estimate a temperature ripple of the power module from the ripple of the maximum conduction loss, and
estimate the junction temperature of the power module by adding an amount of change in the junction temperature of the power module at a time of high-speed driving of the motor and a temperature of a coolant for cooling the power module to the temperature ripple,
wherein the temperature ripple of the power module is estimated using a thermal model.

2. The apparatus of claim 1,
wherein the high-speed driving is a driving condition of the motor in which an average conduction loss of the power module is constant over time and a ripple of conduction loss is within an error range, and
wherein the low-speed driving is a driving condition of the motor in which the average conduction loss of the power module varies over time and the ripple of the conduction loss is outside of the error range.

3. The apparatus of claim 1, wherein the thermal model is a model for estimating the temperature ripple of the power module from conduction loss due to conduction of the power module.

4. The apparatus of claim 1, wherein the one or more processors are further configured for estimating the temperature ripple of the power module by multiplying the ripple of the maximum conduction loss by a gain of the thermal model.

5. The apparatus of claim 2, wherein the thermal model is an RC filter in which a resistor and a capacitor are connected in parallel.

6. The apparatus of claim 5, wherein the thermal model is a model in which the RC filter is provided as at least two RC filters connected in series.

7. The apparatus of claim 1, wherein the amount of change in the junction temperature of the power module at the time of the high-speed driving of the motor is a value obtained by multiplying power loss during the high-speed driving of the motor by thermal resistance, the power loss including conduction loss and switching loss of the power module.

8. The apparatus of claim 1, wherein the ripple (RMCL) of the maximum conduction loss is obtained according to equation:
$$RMCL = \frac{{I}_{} ( {I}_{max} \times R + {V}_{ceo} )}{2} \times \frac{1}{2} \times ( 1 + MI ) ,$$
where Iₘₐₓ is a maximum value of a three-phase current, R is turn-on resistance of the power module, V_{ceo} is a maximum voltage of the power module, and MI is a modulation index.

9. The apparatus of claim 8, wherein the maximum value of the three-phase current is obtained based on a d-axis current and a q-axis current through dq conversion of the three-phase current.

10. The apparatus of claim 9, wherein the maximum value of the three-phase current is obtained according to equation:
$${I}_{} = \sqrt{{I}_{d}^{2} + {I}_{q}^{2}} / \sqrt{2} ,$$
where Iₘₐₓ is the maximum value of the three-phase current, I_{d} is the d-axis current, and I_{q} is the q-axis current.

11. A method of estimating a junction temperature of a power module at a time of low-speed driving of a motor, the method comprising:
determining, by at least a processor, a ripple of a maximum conduction loss due to conduction of the power module at the time of the low-speed driving of the motor;
estimating, by the by at least a processor, a temperature ripple of the power module from the ripple of the maximum conduction loss; and
estimating, by the by at least a processor, the junction temperature of the power module by adding an amount of change in the junction temperature of the power module at a time of high-speed driving of the motor and a temperature of a coolant for cooling the power module to the temperature ripple,
wherein in the estimating of the temperature ripple, the temperature ripple of the power module is estimated using a thermal model.

12. The method of claim 11,
wherein the high-speed driving is a driving condition of the motor in which an average conduction loss of the power module is constant over time and a ripple of conduction loss is within an error range, and
wherein the low-speed driving is a driving condition of the motor in which the average conduction loss of the power module varies over time and the ripple of the conduction loss is outside of the error range.

13. The method of claim 11, wherein the thermal model is a model for estimating the temperature ripple of the power module from conduction loss due to conduction of the power module.

14. The method of claim 11, wherein the estimating of the temperature ripple includes estimating the temperature ripple of the power module by multiplying the ripple of the maximum conduction loss by a gain of the thermal model.

15. The method of claim 12, wherein the thermal model is an RC filter in which a resistor and a capacitor are connected in parallel.

16. The method of claim 15, wherein the thermal model is a model in which the RC filter is provided as at least two RC filters connected in series.

17. The method of claim 11, wherein the amount of change in the junction temperature of the power module at the time of the high-speed driving of the motor is a value obtained by multiplying power loss during the high-speed driving of the motor by thermal resistance, the power loss including conduction loss and switching loss of the power module.

18. The method of claim 11, wherein the ripple (RMCL) of the maximum conduction loss is obtained according to equation:
$$RMCL = \frac{{I}_{} ( {I}_{max} \times R + {V}_{ceo} )}{2} \times \frac{1}{2} \times ( 1 + MI ) ,$$
where Iₘₐₓ is a maximum value of a three-phase current, R is turn-on resistance of the power module, V_{ceo} is a maximum voltage of the power module, and MI is a modulation index.

19. The method of claim 18, wherein the maximum value of the three-phase current is obtained based on a d-axis current and a q-axis current through dq conversion of the three-phase current.

20. The method of claim 19, wherein the maximum value of the three-phase current is obtained according to equation:
$${I}_{} = \sqrt{{I}_{d}^{2} + {I}_{q}^{2}} / \sqrt{2} ,$$
where Iₘₐₓ is the maximum value of the three-phase current, I_{d} is the d-axis current, and I_{q} is the q-axis current.
